(19) United States
(12) Patent Application Publication
(10) Pub. No.: US 2011/0233779 A1
(43) Pub. Date: Sep. 29, 2011

(54) SEMICONDUCTOR DEVICE AND METHOD OF MANUFACTURING THE SAME

(75) Inventors: Makoto Wada, Yokohama-shi (JP); Yosuke Akimoto, Yokohama-shi (JP); Yuichi Yamazaki, Inagi-shi (JP); Masayuki Katagiri, Kawasaki-shi (JP); Noriaki Matsunaga, Chigasaki-shi (JP); Tadashi Sakai, Yokohama-shi (JP); Naoshi Sakuma, Yokohama-shi (JP)

(73) Assignee: KABUSHIKI KAISHA TOSHIBA, Minato-ku (JP)

(21) Appl. No.: 13/052,367

(22) Filed: Mar. 21, 2011

(30) Foreign Application Priority Data
Mar. 24, 2010 (JP) 2010-068430

(51) Int. Cl. H01L 23/532; H01L 21/28; B82Y 99/00; B82Y 40/00

(52) U.S. Cl. 257/751; 438/653; 977/742; 977/842; 977/932; 257/E21.158; 257/E23.157

(57) ABSTRACT

According to one embodiment, a semiconductor device includes an interlayer insulation film provided on a substrate including a Cu wiring, a via hole formed in the interlayer insulation film on the Cu wiring, a first metal film selectively formed on the Cu wiring in the via hole, functioning as a barrier to the Cu wiring, and functioning as a promoter of carbon nanotube growth, a second metal film formed at least on the first metal film in the via hole, and functioning as a catalyst of the carbon nanotube growth, and carbon nanotubes buried in the via hole in which the first metal film and the second metal film are formed.

### CROSS-REFERENCE TO RELATED APPLICATIONS

This application is based upon and claims the benefit of priority from Japanese Patent Application No. 2010-068430, filed Mar. 24, 2010; the entire contents of which are incorporated herein by reference.

### FIELD

Embodiments described herein relate generally to a semiconductor device using carbon nanotubes, and a method of manufacturing this semiconductor device.

### BACKGROUND

In recent years, there has been proposed a method of reducing a wiring resistance by forming carbon nanotubes (CNTs) in a via hole of a multilayer wiring. In this method, TaN/Ti(N)/Co, which functions as a catalyst layer of CNTs, is formed in advance in the via hole, and then a film of CNTs is formed by a chemical vapor deposition (CVD) method. At this time, since the catalyst layer is formed not only within the via hole, but also on the entire surface of the wafer, the CNTs are grown not only in the via hole but also on the entire surface of the wafer. Subsequently, in order to leave the CNTs only in the via hole, the excess CNTs, which are present outside the via hole, are removed by chemical mechanical polishing (CMP). The CNT has such properties that the CNT flexibly bends in the lateral direction, that is, in the horizontal direction, relative to the via hole. Thus, in order to perform CMP, it is necessary to solidify the CNTs by impregnating, a SiO₂ film of Spin on Direct (SOD), into the CNTs.

However, if the CNTs are grown at high density, the CNTs transition to the state in which that amount of the SOD film, which can fully solidify the CNTs, cannot be impregnated in the CNTs. In this case, the CMP process cannot be performed. In order to reduce the via resistance, the realization of the high density of CNTs is indispensable. Thus, it is difficult to make compatible the reduction in via resistance and the CMP process. Moreover, since the CNT itself has a very high resistance to chemical treatment, it is very difficult to etch the CNT itself by CMP.

Besides, when CNTs are grown on the entire surface, there occurs growth of CNTs from the side surface of the via hole. The CNTs, which are grown from the side surface of the via hole, greatly increase the via resistance. In worst cases, the top face of the via is buried by the CNTs that are grown from the side wall, and thus the via is, in fact, broken.

### BRIEF DESCRIPTION OF THE DRAWINGS

FIGS. 1A and 1B are cross-sectional views illustrating the device structure of a semiconductor device according to a first embodiment.

FIGS. 2A to 2H are cross-sectional views illustrating fabrication steps of a semiconductor device according to a second embodiment.

FIGS. 3A and 3B are cross-sectional views illustrating fabrication steps of a semiconductor device according to a third embodiment.

FIGS. 4A and 4B are cross-sectional views illustrating fabrication steps of a semiconductor device according to a fourth embodiment.

FIGS. 5A to 5C are cross-sectional views illustrating fabrication steps of a semiconductor device according to a fifth embodiment.

### DETAILED DESCRIPTION

In general, according to one embodiment, there is provided a semiconductor device using carbon nanotubes. A via hole for connection to a Cu wiring is formed in an interlayer insulation film provided on a substrate including the Cu wiring. A first metal film is formed on the Cu wiring in the via hole, the first metal film functioning as a barrier to the Cu wiring, and functioning as a co-catalyst (promoter) of carbon nanotube growth, and being in contact with a side wall surface of the via hole of the first interlayer insulation film. A second metal film is formed at least on the first metal film in the via hole, the second metal film functioning as a catalyst of the carbon nanotube growth. Carbon nanotubes are formed in the via hole in which the first metal film and the second metal film are formed.

A CNT has such properties that the CNT grows in a direction substantially perpendicular to a catalyst, and it is proposed that the CNT is applied to a contact material of a via of an LSI device. Specifically, after a contact is opened, a film of a catalyst metal is grown, and then CNTs are grown. Subsequently, in order to leave CNTs only in the via, excess CNTs are removed. However, since a CMP process of CNTs is very difficult, a process method which is a substitute for CMP, or a structure which does not use CMP is needed.

### First Embodiment

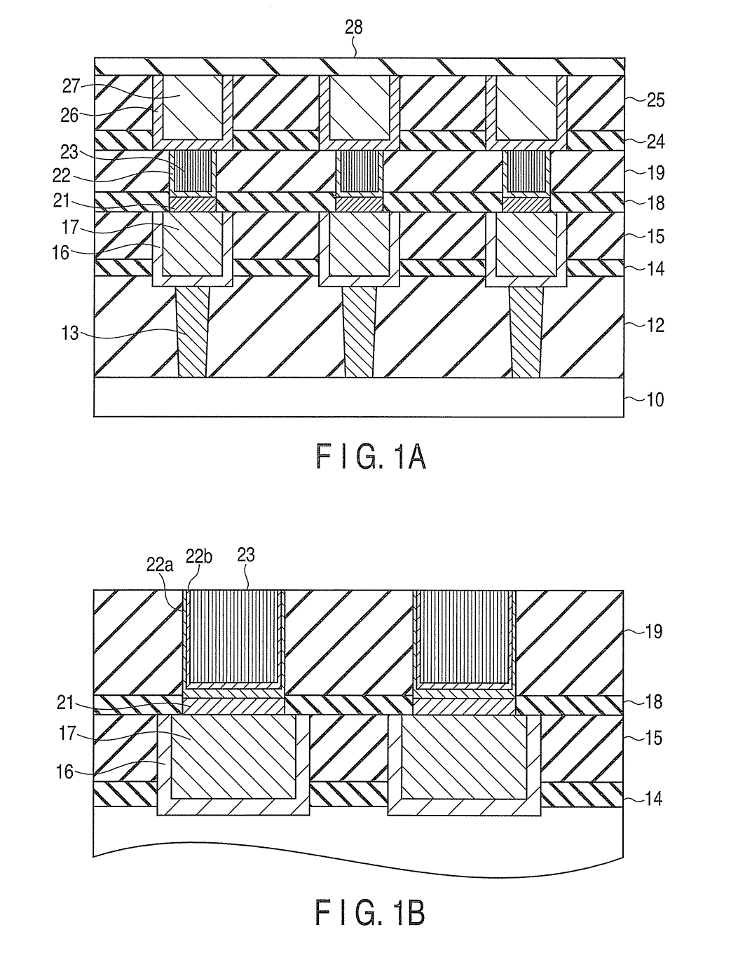

FIG. 1A and FIG. 1B are views for describing a semiconductor device according to a first embodiment. FIG. 1A is a cross-sectional view showing the device structure, and FIG. 1B is a cross-sectional views showing, in enlarged scale, a via part.

Reference numeral 10 in FIG. 1A denotes a semiconductor substrate on which semiconductor elements, such as transistors and capacitors, are formed. An interlayer insulation film (second interlayer insulation film) 12, which is formed of TEOS, is deposited on the semiconductor substrate 10. Contacts 13, which are formed of W, Cu or Al, are formed in this insulation film 12.

A first wiring layer insulation film 15, which is formed of SiOC, is deposited on the insulation film 12 and contacts 13 via a stopper insulation film 14 which is formed of SiCN. A wiring groove, which is continuous with the contact 13, is provided in the insulation film 15. A first wiring 17 of, e.g. Cu, is buried in the wiring groove via a barrier metal 16.

An interlayer insulation film (first interlayer insulation film) 19 of, e.g. TEOS is formed on the insulation film 15 and first wiring 17 via a stopper insulation film 18 which is formed of SiCN. A via hole, which is continuous with the first wiring 17, is formed in the insulation film 19. A first metal film 21, which is formed of Ta or a nitride thereof and functions as a promoter of CNT growth, is selectively formed at a bottom part of the via hole. For example, a TaN film is grown on a Cu film serving as the first wiring 17 by a selective CVD method. A second metal film 22, which functions as a catalyst of CNT growth, is formed on the metal film 21 and on side surfaces of the via hole. Carbon nanotubes (CNTs) 23 are buried in the via hole.

The first metal film 21 is in contact with a lower part of the interlayer insulation film 18 and 19. The first metal film 21 is not formed on the side wall surface of the via hole of the first interlayer insulation film 18 and 19. In this embodiment, as shown in FIG. 1B, the first metal film 21 is in contact with the stopper insulation film 18 and is not in contact with the insulation film 19.

As shown in FIG. 1B, the second metal film 22 has a multilayer structure comprising a Ti film 22a and a Co film 22b. The Co film 22b is a catalyst of CNT growth, and Ni or Fe may be substituted for Co. The Ti film 22a serves as a resistor for ohmic contact between the CNTs 23 and the first wiring 17. A second wiring layer insulation film 25 is formed on the insulation film 19 and CNTs 23 via a stopper insulation film 24. A wiring groove, which is continuous with the CNTs 23, is formed in the insulation film 25, and a second wiring 27 of, e.g. Cu, is buried in the wiring groove via a barrier metal 26. A cap layer 28 is formed on the insulation film 25 and second wiring 27.

As has been described above, in the present embodiment, the first metal film 21, which is formed of Ta or a nitride thereof and is selectively formed on only the Cu wiring 17 at the bottom of the via hole, functions as the promoter of CNT growth. Thus, all the CNTs 23 grow basically from the bottom part of the via hole, and growth of CNTs from side surfaces of the via hole is suppressed. Since CNTs, which grow from the side wall, become electrically conductive via a barrier metal, it is desirable, from the standpoint of reduction in via resistance, that there is no growth from the side wall. By growing the CNTs from only the bottom surface of the via, the number of CNTs, which directly contribute to electrical conductance, becomes remarkably larger than in the prior art, and the reduction in via resistance can be realized.

In addition, the TaN film, which serves as the first metal film 21, is not formed on the side surfaces of the via hole, and only the Ti/Co layer, which serves as the second metal film 22, is formed on the side surfaces of the via hole. In this case, it is indispensable that the TaN film is a continuous film, from the standpoint of ensuring barrier properties, and a certain thickness of the TaN film is needed. On the other hand, the Ti/Co layer is a discontinuous film in a dispersed state, and may have a very small thickness of about 0.5 nm. Although there is a case in which the Ti layer becomes a discontinuous film, the thickness of the Ti layer may be small at any case. Accordingly, the reduction in opening area of the via due to the Ti/Co layer, which is formed on the side surfaces of the via hole, can be decreased, and the area of occupation by the CNTs, which contribute to electrical conduction, increases. Therefore, further reduction in via resistance is possible.

Since the first metal film 21 must have a promoter function, TiN may be used in place of TaN as the material of the first metal film 21. In addition, a single-layer film of Co may be used in place of the multilayer film of Ti/Co as the material of the second metal film 22.

### Second Embodiment

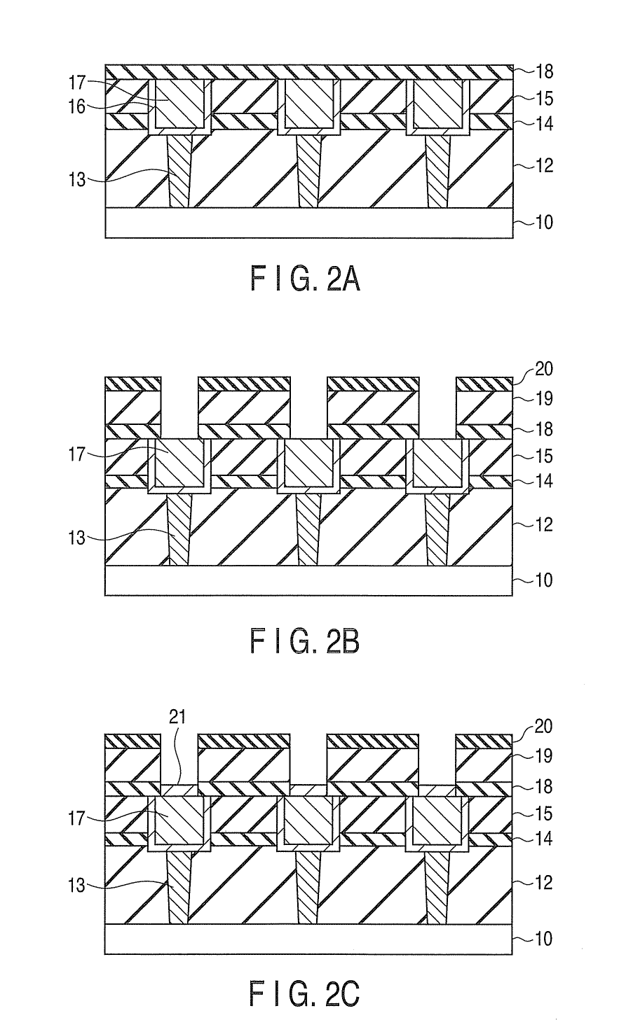

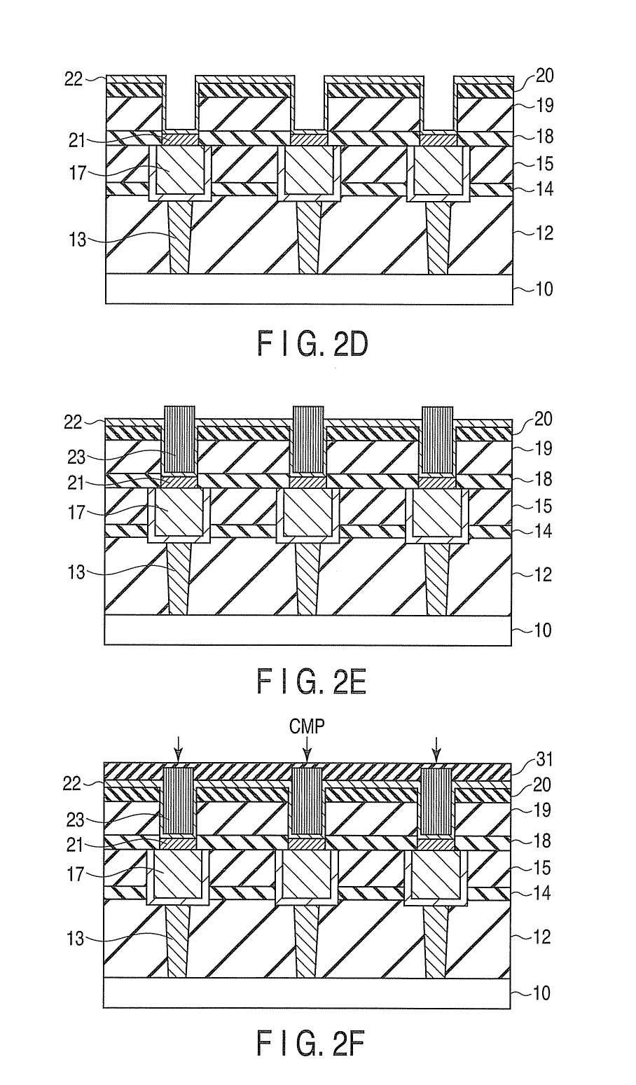

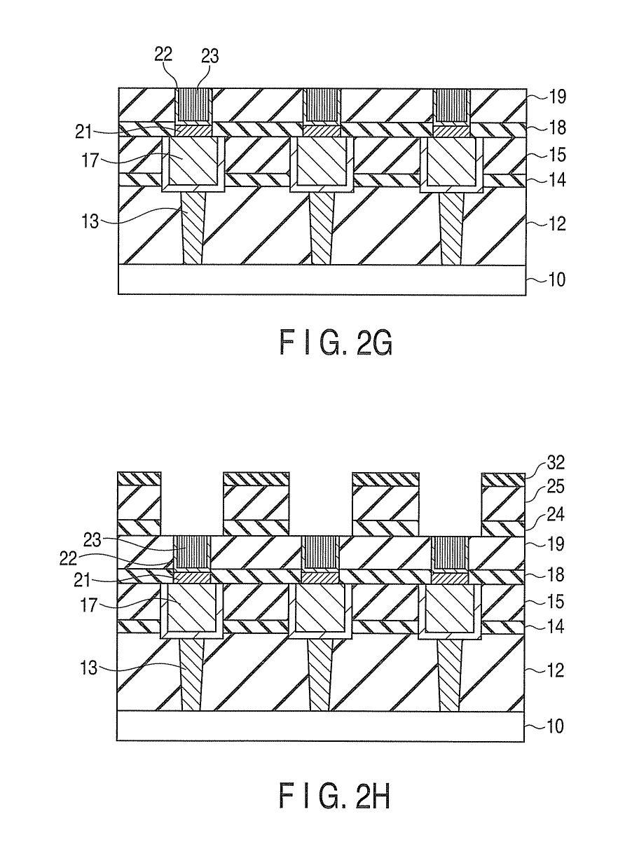

FIGS. 2A to 2H are cross-sectional views illustrating fabrication steps of a semiconductor device according to a second embodiment.

To start with, as shown in FIG. 2A, an interlayer insulation film 12, which is formed of, e.g. TEOS, is formed on a semiconductor substrate 10 on which semiconductor elements such as transistors and capacitors are formed. Then, contacts 13 of, e.g. W or Cu, for connecting the semiconductor elements and an upper wiring are formed in the insulation film 12. Subsequently, a stopper insulation film 14 of, e.g. a SiCN film for process control of a wiring layer is formed on the insulation film 12 by, e.g. CVD. A first wiring insulation film 15 of, e.g. SiOC is formed on the insulation film 14.

Subsequently, although not shown, a cap film of, e.g. SiO₂, which functions as a protection film for protection from damage due to RIE or CMP, is formed on the insulation film 15. Then, after performing a resist coating/lithography step (not illustrated), a single damascene wiring structure is formed by RIE.

Thereafter, a Ta film 16 is formed as a barrier metal in the damascene wiring structure. Further, after forming a Cu seed film which becomes a cathode electrode of electrolytic plating, a Cu film (first wiring) 17 which functions as an electrically conductive material is formed by, e.g. an electrolytic plating method. Then, an excess portion of the Cu film 17 is polished and removed by CMP. At last, a diffusion prevention film 18, which prevents surface diffusion of Cu and serves as a process stopper layer of the upper wiring structure, is formed, and a lower wiring is completed. The structure, which has been fabricated up to the lower wiring, is used as an underlying substrate.

The above-described process is not different from the conventional process of Cu wiring formation. Thus, the materials and fabrication methods of the insulation films 12, 14, 15 and 18, contacts 13, barrier metal 16 and first wiring 17 may properly be varied according to specifications.

Next, as shown in FIG. 2B, an interlayer insulation film 19 is formed on the diffusion prevention film 18. The insulation film 19 is formed of, e.g. a SiOC film, and is formed by, e.g. a CVD method or a coating method. In order to lower the dielectric constant, the insulation film 19 may be a film including minute pores. Then, a cap film 20, which becomes a protection film for protection from RIE damage or CMP damage of the insulation film 19, is formed. The cap film 20 is, for example, a SiO₂ film or SiOC film. In the case where the insulation film 19 is a film which is resistant to RIE damage, for example, a TEOS film or a SiOC film including no minute pores, the cap film 20 may not particularly be formed. Subsequently, after performing a resist coating/lithography step (not illustrated), a via hole, which is continuous with the Cu film 17, is opened by RIE.

Next, as shown in FIG. 2C, a first metal film 21, which is formed of, e.g. TaN, is selectively formed on the surface of the Cu film 17 which is exposed at the bottom of the via hole. In this case, in the conventional process, a TaN/Ti(N)/Co film, which functions as a catalyst layer of CNT growth, is formed. In this structure, however, CNTs would grow on the entire surface of the wafer, as described above. It is thus difficult to perform a CMP process of the CNTs.

To cope with this problem, in the present embodiment, as shown in FIG. 2C, selective CVD of a metal, which selectively grows on only the Cu at the bottom of the via, is performed, and the metal film 21 is selectively grown on only the Cu film 17 which is exposed at the bottom of the via hole. The selectively grown metal may be a metal seed which enables selective CVD on Cu, has diffusion barrier properties to the Cu of the wiring layer and the catalyst metal, and has a promoter function which promotes CNT growth. The metal, which meets these conditions, is, for instance, Ta, W, Ru or Co. It is known that such metal materials selectively grow on Cu by CVD (C.-C. Yang, et al., IEEE Int. Interconnect Technology Cof., 4.40 (2009)). Furthermore, it is known that such metal materials have catalyst effects for CNT growth, and function as promoters of CNTs when films of such materials are used as continuous films.

As regards Co, the Co in an elemental metal state has the same composition as Co which functions as a catalyst metal, and has no barrier properties to the Co of the catalyst metal, and, as a result, a film of the catalyst metal Co cannot dispersedly be formed. Thus, when Co is selectively grown, a nitriding process is performed after a Co film is formed or while a Co film is being formed. Thereby, the surface or the entirety of the selectively grown Co film is nitrided, and a Co nitride is formed. As regards the nitriding process, the nitriding process may be replaced with an oxidizing process, and an oxide of Co may be formed. Although Ta, Ru and W can be used as elemental metals, these metals may be subjected to a nitriding process or an oxidizing process, like Co, from the standpoint of an improvement of barrier properties. When a nitride film is formed, nitrogen may be introduced in a gas during the selective growth of a metal film by CVD, or the surface of a metal film, after selective growth, may be nitrided. A metal film, which is selectively grown, needs to be, at least, a continuous film, from the standpoint of diffusion barrier properties, and the metal film needs to have a film thickness of 1 nm or more. Moreover, it is also possible to use the TiN film that has the promoter operation as the first metal film 21.

Next, as shown in FIG. 2D, a film of Ti/Co is formed on the entire surface as a second metal film 22. Ti has a function of terminating an end face of CNTs as a carbide of Ti, and is effectively for good interface contact of CNTs, and is possible to omit. Co is a main catalyst of CNT, and is necessary and indispensable for the growth of CNTs. As the catalyst of CNT growth, Ni or Fe, other than Co, can be used. In order to grow high-density CNTs, it is desirable that Co be a discontinuous film in a dispersed state.

Next, as shown in FIG. 2E, CNTs 23, which function as an electrically conductive layer, is formed. CVD is used in the formation of the CNTs 23. In the conventional structure, since TaN/TiN which functions as a promoter and Co which is a catalyst metal are formed on the entire surface of the wafer, the CNTs grow on the entire surface of the wafer. On the other hand, in the present embodiment, TaN which functions as a promoter is selectively formed on only the bottom of the via hole. Thus, the CNTs grow at a higher speed and with a higher density on the bottom of the via hole, compared to the upper planar part on which the promoter is not formed. By making use of this characteristic, the CNTs 23 can selectively be grown only in the via hole.

A hydrocarbon gas, such as methane or acetylene, or a mixture gas thereof, is used as a carbon source of CVD for forming the CNTs, and hydrogen or a noble gas is used as a carrier gas. The upper limit of the process temperature is about 1000° C., the lower limit of the process temperature is about 200° C., and it is particularly desirable that the temperature for growth be about 350° C. It is effective to use a remote plasma, and further to apply a voltage by disposing an electrode at an upper part of the substrate in order to eliminate ions and electrons. The application voltage in this case should preferably be about 0 to ±100 V. By controlling the temperature for growth and the application voltage, a clear difference can be made in CNT growth speed between the inside of the via hole and the upper planar part, and the CNT 23 can selectively be grown only in the via hole.

Next, a SiO₂ film of SOD, for example, is impregnated in the CNTs 23, and CMP of the CNTs 23 is performed. Since the CNTs 23 in the via hole are grown at high density, the SOD film is not easily impregnated in this CNTs 23. However, on the upper planar part, CNTs are not basically grown, or even if CNTs are grown, the speed of growth is low and the density of CNTs is low. Thus, as shown in FIG. 2F, an SOD film 31 is formed on the upper planar part, and the CNTs 23, which are grown in the via hole, are fixed by the SOD film 31.

By this structure, the CMP process of the CNTs 23, which is difficult in the prior art, can easily be performed. In addition, by managing the speed of growth or the time of growth of the CNTs 23 in the via hole, the length of the CNTs 23, which excessively project to the upper part, can be decreased. Accordingly, the amount of CNTs, which is removed by CMP, decreases. Therefore, even the CNTs having high resistance to chemical treatment of CMP can easily be polished by CMP by mainly using a mechanical polishing component. In addition, by decreasing the length of the excessively projecting CNTs 23, almost the entirety of the CNTs 23 is fixed by the insulation film 19. Therefore, CMP can directly be performed, without impregnating SOD. FIG. 2G is a cross-sectional view showing the structure after the CMP process.

Next, as shown in FIG. 2H, a stopper layer 24 for process control of a wiring layer, a second wiring layer insulation film 25, and a cap film 32 which serves as a protection film for protection from damage are formed. The details of the formation of these parts are the same as in the process of fabricating the lower wiring layer, and a description thereof is omitted here. Subsequently, after performing a resist coating/lithography step (not illustrated), a damascene wiring structure is formed by RIE.

Thereafter, like the process of fabricating the lower wiring, metal films (barrier metal 26 and Cu film 27) are formed in the wiring groove, a thermal stabilization process and a CMP process are formed, and a diffusion barrier film 28 is formed. Thus, the structure shown in FIG. 1 is completed.

In the present embodiment, as described above, in the stage preceding the formation of the CNTs 23, as shown in FIG. 2C, the TaN film 21, which functions as the promoter, is formed on only the surface of the underlying Cu wiring 17, which is exposed in the via hole, and the Ti/Co film 22, which function as the catalyst, is formed on the side wall of the via hole. Thereby, the CNTs 23 can selectively be formed only in the via hole. Therefore, compared to the case in which the CNTs 23 are formed on the entire surface, the CMP of the CNTs 23 is very easy. Specifically, while the CNTs are used as the contact material in the via hole, the via resistance can be reduced and the process is simplified. Furthermore, since the growth of the CNTs 23 from the side wall of the via hole can be suppressed, the reduction in via resistance is realized, thereby contributing to the improvement of device characteristics.

The manufacturing process can be simplified by using TIN in place of TaN as the material of the first metal film 21 and using a single-layer film of Co in place of the multilayer film of Ti/Co as the material of the second metal film 22.

### Third Embodiment

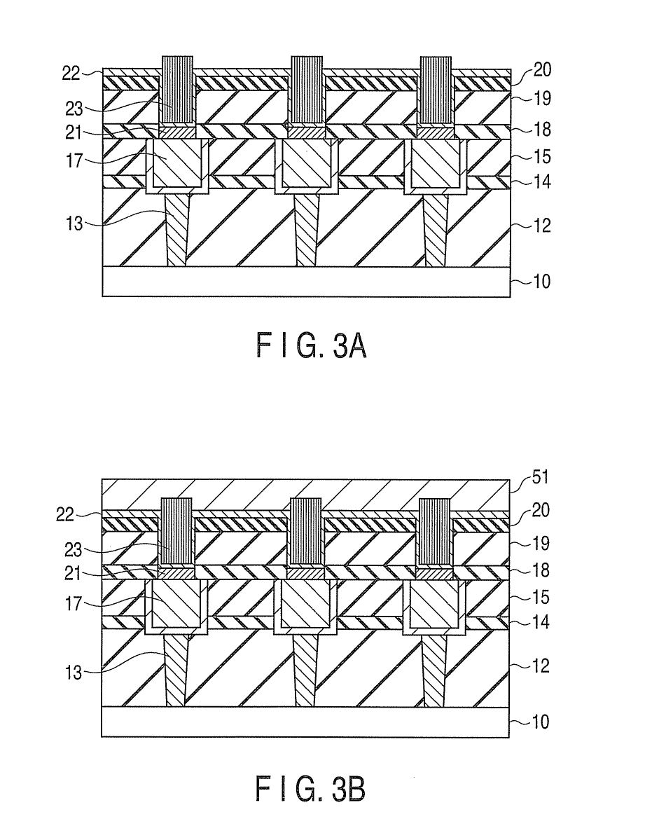

FIGS. 3A and 3B are cross-sectional views illustrating fabrication steps of a semiconductor device according to a third embodiment. The parts common to those in FIGS. 2A to 2H are denoted by like reference numerals, and a detailed description is omitted.

The third embodiment differs from the above-described second embodiment in that a metal film is formed in place of the SOD film, in a pre-process of CMP of the CNTs.

The fabrication steps up to FIG. 2E are common between the second embodiment and the third embodiment. As shown in FIG. 3A, CNTs 23 are grown in the via hole, and an upper end of the CNTs 23 is projected higher than the upper end of the via hole. Then, as shown in FIG. 3B, a third metal film 51, in place of the SOD film, is formed on the entire surface. Specifically, the metal film 51 is formed on the CNTs 23 and Ti/Co film 22. The metal film 51 is, for example, W, Al, or Ti. Since the CNTs 23 are fixed by the insulation film 19, it is not particularly necessary to impregnate a metal in the CNTs 23, and the CNTs 23 can directly be polished by CMP.

In this manner, in the present embodiment, the process condition of metal CMP can be used by using the metal film 51 in place of the SOD film which is the impregnation material of CMP. This increases the degree of freedom of process design, and reduces the manufacturing cost.

### Fourth Embodiment

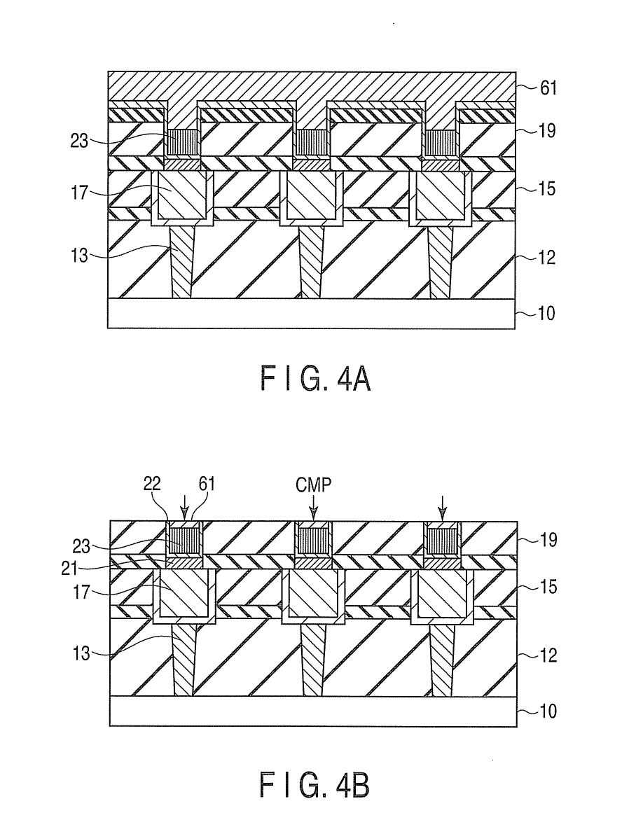

FIGS. 4A and 4B are cross-sectional views illustrating fabrication steps of a semiconductor device according to a fourth embodiment. The parts common to those in FIGS. 2A to 2H are denoted by like reference numerals, and a detailed description is omitted.

The fourth embodiment differs from the above-described first embodiment in that CNTs are grown up to an intermediate part of the via hole, and a metal film is formed in the other part of the via hole.

The fabrication steps up to FIG. 2D are common between the second embodiment and the fourth embodiment. In the present embodiment, as shown in FIG. 4A, the speed of growth and time of growth of the CNTs 23 are controlled so that the CNTs 23 are grown up to an intermediate part of the via hole. Then, a third metal film 61 is formed on the entire surface, and the other part of the via hole is filled with the metal film 61. The metal film 61, which is formed, should preferably be a metal which reacts with the CNTs 23 and can easily form a metal carbide, and which is, for example, Ti. By forming such a metal carbide, a good interface contact structure of carbon nanotubes is formed, and the contact resistance can be reduced.

In addition, in the step of forming the metal film, an upper end portion of the CNTs 23 may be subjected to a pre-process, such as an ashing process by O₂ or CO or a milling process by He or Ar. Thereby, the upper end portion of the CNTs 23 is opened, and all multi-walls of the CNTs can contribute to electrical conduction, and therefore the via resistance can further be reduced.

Subsequently, as shown in FIG. 4B, an excess part of the metal film 61, which lies on the upper part, is removed by CMP, and thus a via structure is completed. This CMP process is simple metal CMP, and the conventional metal CMP process is applicable. Therefore, the CMP process can be performed more easily.

As has been described above, in the present embodiment, the growth of the CNTs 23 is stopped at an intermediate part of the via hole, and the other part of the via hole is filled with the metal film 61. Thereby, the CMP of the CNTs 23 is unnecessary. Thus, the easiness of the process is improved, and the manufacturing cost can further be reduced.

### Fifth Embodiment

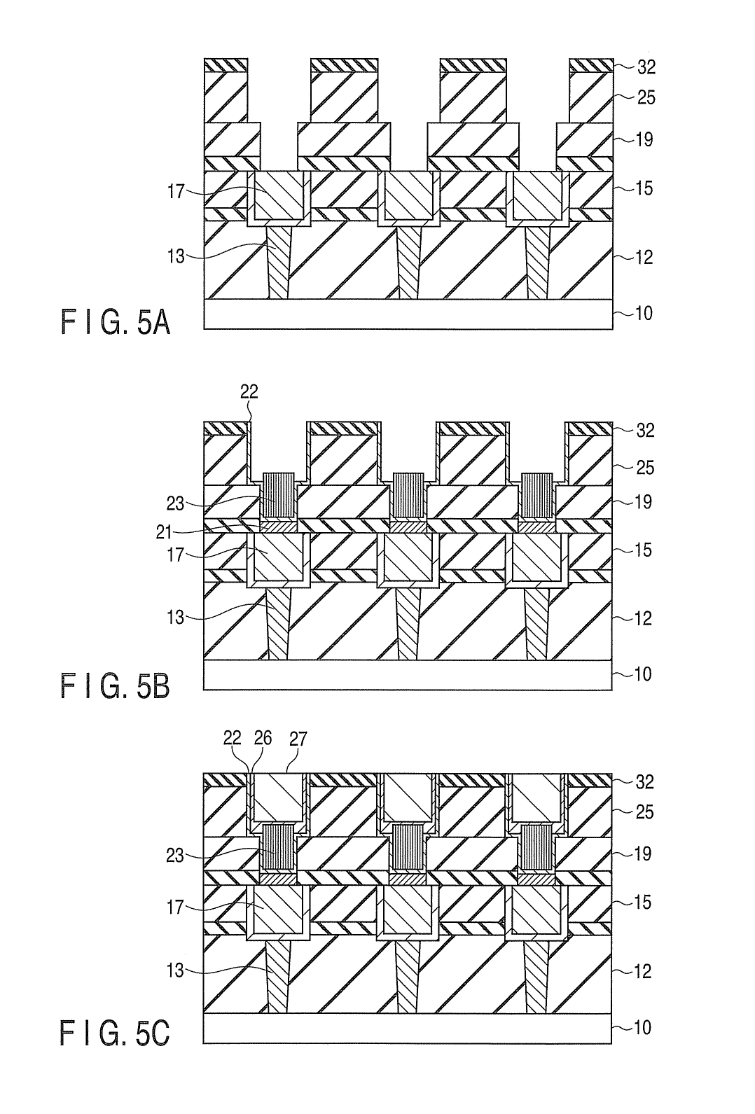

FIGS. 5A, 5B and 5C are cross-sectional views illustrating fabrication steps of a semiconductor device according to a fifth embodiment. The parts common to those in FIGS. 2A to 2H are denoted by like reference numerals, and a detailed description is omitted.

In the present embodiment, unlike the process of separately fabricating the via structure and the upper wiring structure as in the second, third and third embodiments, a dual damascene process of simultaneously forming the via structure and the upper wiring structure is applied.

To begin with, as shown in FIG. 5A, a via hole and an upper wiring groove are formed on the lower Cu wiring. The method of the formation corresponds to a dual damascene method of the conventional LSI process technology. Specifically, after the lower Cu wiring 71 shown in FIG. 2A is formed, an interlayer insulation film 19 and a second wiring layer insulation film 25 are formed. Further, a cap film 32, which serves as a protection film for protection from damage, is formed. Then, after forming a wiring groove in the insulation film 25, a via hole which is continuous with the lower Cu wiring 17 is formed in the insulation film 19.

Next, as shown in FIG. 5B, a first metal film 21 is selectively grown by CVD on only the Cu wiring 17 at the bottom of the via hole, and the process up to the step of growth of the CNTs 23 is performed by the same method as in the second embodiment. The CNTs 23 are grown up to a level higher than the upper end of the via hole, and is made to project into the wiring groove. Thereby, the structure is obtained in which the CNTs 23 are grown only in the via part of the dual damascene wiring structure. In the meantime, it is not always necessary that the CNTs 23 be grown up to a level higher than the upper end of the via hole. The CNTs 23 may be grown up to a level equal to the level of the upper end of the via hole, or up to an intermediate part of the via hole.

Subsequently, as shown in FIG. 5C, a metal film formation process for an upper wiring is performed. In this process, a barrier metal 26 is formed in the wiring groove, a metal film is then formed on the entire surface, and thereafter CMP is performed. Thereby, the wiring structure, in which the Cu film 27 is buried as a second wiring in the wiring groove, can be completed.

As has been described above, in the present embodiment, since the CMP process in the via process is needless, the easiness of the process can be improved and the manufacturing cost can be reduced. After the growth of the CNTs, like the fourth embodiment, the step of opening the upper end portion of the CNTs may be performed prior to the process of forming the metal film. Thereby, the via resistance can further be reduced. Moreover, by using a metal (e.g. Ti), which forms a metal carbide, as a barrier metal of the upper wiring, a good interface contact structure of carbon nanotubes is formed, and the contact resistance can further be reduced.

### (Modifications)

The present invention is not limited to the above-described embodiments. The first metal film, which functions as a promoter for CNT growth, is not necessarily be limited to Ta or TaN, and use may be made of Ru, W, or a nitride thereof. Further, a nitride of Co may be used. The second metal film, which functions as a catalyst for CNT growth, is not limited to Co, and use may be made of Ni or Fe.

The second metal film may not necessarily be formed on the entire surface, and the second metal film may be selectively formed on only the surface of the first metal film. However, from the standpoint of the manufacturing process, it is easier to form the second metal film over the entire surface. In the present invention, the first metal film is formed on only the bottom part of the via hole. Thus, even if the second metal film is formed over the entire surface, the selective growth of CNTs from the bottom of the via hole is possible. Thus, the process can be made easier.

The conditions for forming the first and second metal films, and also the conditions for forming the CNTs (e.g. CVD gas, temperature, etc.) can properly be varied according to specifications.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first interlayer insulation film provided on a substrate including a first Cu wiring;
a via hole formed in the first interlayer insulation film on the first Cu wiring;
a first metal film formed on the first Cu wiring in the via hole, functioning as a barrier to the first Cu wiring, and functioning as a promoter of carbon nanotube growth, and being in contact with a side wall surface of the via hole of the first interlayer insulation film;
a second metal film formed at least on the first metal film in the via hole, and functioning as a catalyst of the carbon nanotube growth; and
carbon nanotubes formed in the via hole in which the first metal film and the second metal film are formed.

2. The device of claim 1, wherein the second metal film is formed on an upper surface of the first interlayer insulation film.

3. The device of claim 1, wherein the first metal film is a film of one of Ta, Ru and W, or a nitride of one of Ta, Ru, W and Ti, and the second metal film is a discontinuous film of one of Co, Ni and Fe or a multilayer film of Ti and one of Co, Ni and Fe.

4. The device of claim 1, wherein the carbon nanotubes are formed up to an intermediate part of the via hole, and a third metal film is formed on the carbon nanotubes in the via hole.

5. The device of claim 1, wherein the substrate includes a semiconductor substrate on which a semiconductor element is formed, a second interlayer insulation film formed on the semiconductor substrate, a metal contact formed in the second interlayer insulation film, a first wiring layer insulation film formed on the second interlayer insulation film and the metal contact, a first wiring groove formed in the first wiring layer insulation film, and the first Cu wiring formed in the first wiring groove.

6. The device of claim 5, further comprising a second wiring layer insulation film formed on the first interlayer insulation film and the carbon nanotubes, a second wiring groove formed in the second wiring layer insulation film in a manner to be partly continuous with the carbon nanotubes, and a second Cu wiring formed in the second wiring groove.

7. A method of manufacturing a semiconductor device, comprising:
forming a via hole in an interlayer insulation film formed on the Cu wiring;
forming a first metal film on the Cu wiring which is exposed in the via hole, the first metal film functioning as a barrier to the Cu wiring and functioning as a promoter of carbon nanotube growth;
forming a second metal film at least on the first metal film in the via hole in which the first metal film is formed, the second metal film functioning as a catalyst of the carbon nanotube growth; and
growing carbon nanotubes from a bottom part of the via hole in which the first metal film and the second metal film are formed, thereby forming the carbon nanotubes in the via hole.

8. The method of claim 7, wherein the second metal film is formed on the first metal film and is formed on a side wall surface in the via hole and on an upper surface of the interlayer insulation film.

9. The method of claim 7, wherein the first metal film is formed by using a film of one of Ta, Ru and W, or a nitride of one of Ta, Ru, W and Ti, and the second metal film is formed by using a discontinuous film of one of Co, Ni and Fe, or a multilayer film of Ti and one of Co, Ni and Fe.

10. The method of claim 8, wherein the carbon nanotubes are grown higher than an upper end of the via hole.

11. The method of claim 10, wherein after the carbon nanotubes are formed in the via hole, a spin coat film is formed on the second metal film and then the carbon nanotubes and the spin coat film are polished by CMP.

12. The method of claim 10, wherein after the carbon nanotubes are formed in the via hole, a third metal film is formed on the second metal film and then the carbon nanotubes and the third metal film are polished by CMP.

13. The method of claim 8, wherein after the carbon nanotubes are grown up to an intermediate part of the via hole, a third metal film is formed in the via hole and on the second metal film, and then the third metal film and the second metal film are polished by CMP.

14. The method of claim 7, wherein the carbon nanotubes are grown by CVD by using, as a carbon source, a hydrocarbon gas or a mixture gas of hydrocarbon gases, and using hydrogen or a noble gas as a carrier gas.

15. A method of manufacturing a semiconductor device, comprising:
providing a via hole in an interlayer insulation film formed on the Cu wiring, and providing a wiring groove, which is continuous with the via hole, in a wiring insulation film formed on the interlayer insulation film;
forming a first metal film on the Cu wiring which is exposed in the via hole, the first metal film functioning as a barrier to the Cu wiring and functioning as a promoter of carbon nanotube growth;
forming a second metal film at least on the first metal film in the via hole in which the first metal film is formed, the second metal film functioning as a catalyst of the carbon nanotube growth;
growing carbon nanotubes from a bottom part of the via hole in which the first metal film and the second metal film are formed, and forming the carbon nanotubes in the via hole; and
forming a wiring metal, which is connected to the carbon nanotubes, in the wiring groove.

16. The method of claim 15, wherein the second metal film is formed on the first metal film and is formed on a side wall surface in the via hole and on an upper surface of the interlayer insulation film.

17. The method of claim 15, wherein the first metal film is formed by using a film of one of Ta, Ru and W, or a nitride of one of Ta, Ru, W, and Ti, and the second metal film is a discontinuous film of one of Co, Ni and Fe or a multilayer film of Ti and one of Co, Ni and Fe.

18. The method of claim 15, wherein the carbon nanotubes are grown until an upper end of the carbon nanotubes projects into the wiring groove.

19. The method of claim 15, wherein the carbon nanotubes are grown by CVD by using, as a carbon source, a hydrocarbon gas or a mixture gas of hydrocarbon gases, and using hydrogen or a noble gas as a carrier gas.

20. The device of claim 1, wherein the first metal film is in contact with a lower part of the first interlayer insulation film and is not formed on the side wall surface of the via hole of the first interlayer insulation film.
